(19) United States
(12) Patent Application Publication
(10) Pub. No.: US 2008/0048284 A1
(43) Pub. Date: Feb. 28, 2008

(54) Image sensor and fabrication method thereof

(75) Inventor: Jun Han Yun, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DONGBU HITEK CO., LTD.

(21) Appl. No.: 11/892,913

(22) Filed: Aug. 28, 2007

(30) Foreign Application Priority Data
Aug. 28, 2006 (KR) 10-2006-0081965

(51) Int. Cl. H01L 31/0232; H01L 21/00

(52) U.S. Cl. 257/432; 438/70; 257/E31.127

(57) ABSTRACT

An image sensor includes a semiconductor substrate having a pixel region and a peripheral region defined therein and having a pixel array formed in the pixel region; a PMD layer formed on the semiconductor substrate; at least one IMD layer formed over the PMD layer, wherein a region of the IMD layer formed on the pixel array is etched to a specific depth; a color filter array formed on the etched IMD layer; and a micro lens array formed on the color filter array, wherein the micro lens array is formed to have consecutive curves without any gap between neighboring lenses.

### RELATED APPLICATION

The application is based upon and claims the benefit of priority to Korean Patent Application No. 10-2006-0081965, filed on Aug. 28, 2006, the entire contents of which are incorporated herein by reference.

### BACKGROUND

1. Technical Field

The embodiment relates to an image sensor and a fabrication method thereof.

2. Background

In recent years, a greater number of pixels per unit area are formed in line with the trend toward miniaturization and multiple pixels of an image sensor. As the size of the pixel has been reduced, the size of a color filter and a micro lens layer formed as an on-chip on the upper part has also been reduced.

As the size of the unit pixel is reduced, the photodiode region for receiving light shrinks and sensitivity thereof is reduced accordingly. In order to compensate for the reduced sensitivity, more light must be received. Solutions for this purpose can include a method of extending an opening unit, a method of forming a focusing micro lens on the upper part, etc.

The opening unit is generally formed of a metal layer. The metal layer serves as a metal line and an optical shield. In refracting light, which is incident on the unit pixel and is then incident over the shield layer, directing the opening unit through the focus lens and then focusing the light, the degree in which lenses are attached or detached as the focus lens is increased in its size varies slightly. Accordingly, there is a problem in that the uniformity of an image is degraded.

Further, underlying color separation layers are influenced and information of a neighboring color separation layer is mixed and input, resulting in poor color reproducibility and contrast. It is also difficult to form a fine pattern at the time of alignment exposure due to degraded photo resolutions depending on mixed pigments when the color separation layers are formed. An upper planarization layer is needed because of overlapping or space formed between the color separation layers, thereby requiring additional fabricating processes.

FIG. 1 is a schematic view showing the structure of a conventional image sensor.

The conventional image sensor, as shown in FIG. 1, includes a pixel region and a peripheral region. The pixel region includes a pixel array 10 and a color filter array 60. A PMD layer 20 is formed on the pixel array 10. First, second, and third IMD layers 30, 40, and 50 are formed over the PMD layer 20.

In a method of fabricating the conventional image sensor, after a passivation film 80 is formed, array etch is performed and the color filter array 60 is formed. Micro lenses 70 are disposed on the color filter array 60. Thus, the image sensor capable of reducing the focal length is provided.

However, in the method of fabricating the conventional image sensor, in order to form the micro lenses 70, a photoresist is coated by a spin-coating method and exposure is performed. In this case, since the step occurs between the pixel region and the peripheral region, defocusing is occurred due to the difference in the focal length, which is caused by exposure. Further, there is a difficulty in that a specific dummy pattern must be designed and inserted into the boundary of the pixel region and the peripheral region.

### SUMMARY

It is, therefore, an object of the present application to provide an image sensor and a fabrication method thereof, in which uniform micro lenses can be formed and the sensitivity of a device can be improved.

In accordance with an aspect of the present application, there is provided an image sensor including a semiconductor substrate having a pixel region and a peripheral region defined therein and having a pixel array formed in the pixel region, a PMD layer formed on the semiconductor substrate, at least one IMD layer formed over the PMD layer, wherein a region of the IMD layer formed on the pixel array is etched to a specific depth, a color filter array formed on the etched IMD layer, and a micro lens array formed on the color filter array. The micro lens array is formed to have consecutive curves without any gap between neighboring lenses.

Further, in accordance with the present application, the micro lens array is formed on the surface of the color filter array.

In accordance with another aspect of the present application, there is provided a method of fabricating an image sensor, including the steps of providing a semiconductor substrate in which a pixel region and a peripheral region are defined, forming a pixel array in the pixel region, forming a PMD layer on the resulting structure, forming at least one IMD layer over the PMD layer, etching the IMD layer formed on the pixel array to a specific depth, forming a color filter array in the etched IMD layer, coating a photoresist on the color filter array to form a photoresist layer having a flat surface, and hardening the photoresist layer, coating a photoresist for forming a dummy micro lens array on the photoresist layer, and performing exposure on the photoresist to form the dummy micro lens array, and performing etch on the dummy micro lens array and the photoresist layer and forming a micro lens array on the color filter array.

Further, in accordance with the present application, the micro lens array is formed on the surface of the color filter array.

Furthermore, in accordance with the present application, the etching on the IMD layer is performed by using a Reactive Ion Etch (RIE) method.

Further, in accordance with the present application, the etching on the dummy micro lens array and the photoresist layer is performed by using an isotropic dry etch method.

Furthermore, in accordance with the present application, the hardening of the photoresist layer is performed by thermal treatment.

In accordance with the present application, there are advantages in that uniform micro lenses can be formed and the sensitivity of an image sensor can be improved.

### BRIEF DESCRIPTION OF THE DRAWINGS

The accompanying drawings, which are included to provide a further understanding of the invention and are incorporated in and constitute a part of this application, illustrate embodiments consistent with the invention and together with the description serve to explain the principles of the invention. In the drawings:

FIG. 1 is a cross-sectional view of a process explaining a method of forming a device isolating layer using a dummy pattern in the related art, according to one exemplary embodiment.

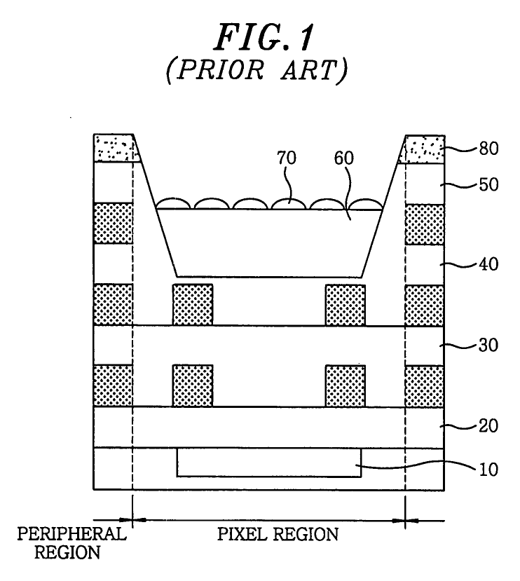

FIG. 2 illustrates the first step in a series of a method of fabricating an image sensor, according to one exemplary embodiment.

FIG. 3 illustrates the second step in a series of a method of fabricating an image sensor, according to one exemplary embodiment.

FIG. 4 illustrates the third step in a series of a method of fabricating an image sensor, according to one exemplary embodiment.

FIG. 5 illustrates the fourth step in a series of a method of fabricating an image sensor, according to one exemplary embodiment.

### DETAILED DESCRIPTION OF THE DRAWINGS

In the description of embodiments in accordance with the present application, in the case where it is described that each layer (film), region, pattern or structure are formed “on/above/over/upper” or “down/below/under/lower” of a substrate, each layer (film), a region, a pad or patterns, it can be construed that the layer (film), region, pad, pattern or structures are directly brought in contact with the substrate, layer (film), region, pad or patterns, or that another layer (film), region, pad, pattern or other structures are additionally formed therebetween. Accordingly, the meaning thereof must be determined based on the technical spirit of the present application.

Hereinafter, an embodiment of the present application will be described in detail with reference to the accompanying drawings.

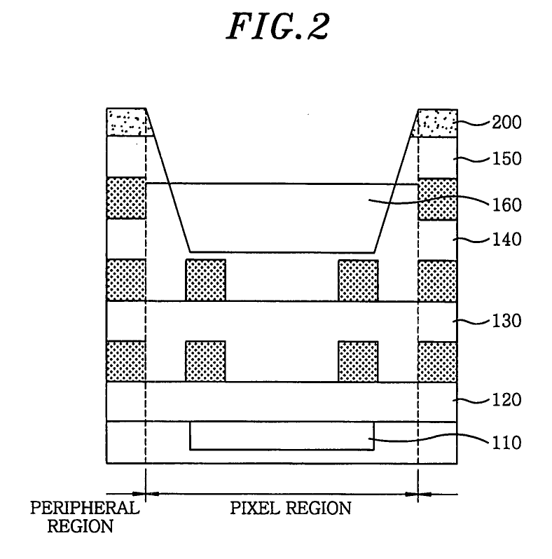

FIGS. 2 to 5 are views sequentially illustrating a method of fabricating an image sensor in accordance with the present application.

In the fabrication method of the image sensor according to one embodiment, as shown in FIG. 2, a semiconductor substrate in which a pixel region and a peripheral region are defined is provided. A pixel array 110 can be formed in the pixel region.

The pixel array 110 can include a number of photodiodes to form micro pixels. Since the resolution of an image depends on the number of the photodiodes, a microstructure of a unit pixel depending on pixels for higher resolutions and miniaturization thereof is performed.

A PMD layer 120 can be formed on the resulting structure and at least one IMD layer can be formed on the PMD layer 120. In FIG. 2, an example in which first, second, and third IMD layers 130, 140, and 150 are formed is shown. However, the number of the IMD layers can be increased or decreased depending on a design choice.

A passivation film 200 may be further formed on the third IMD layer 150.

Thereafter, the third IMD layer 150 disposed over the pixel array 110 can be etched to a specific depth. In this case, the passivation film 200 formed on the third IMD layer 150 can also be etched.

In accordance with the present application, the third IMD layer 150 may be etched by a Reactive Ion Etch (RIE) method.

A color filter array 160 can be formed in the third IMD layer 150 etched to a specific depth.

The color filter array 160 can be formed for the purpose of color separation. The color filter array 160 may be formed in a primary color type or a complementary color type. The color filter array 160, formed as the primary color type, has a red, green or blue color. Further, the color filter array 160, formed as the complementary color type, can have a cyan, yellow or magenta color. The color filter array 160 may be formed from organic substances.

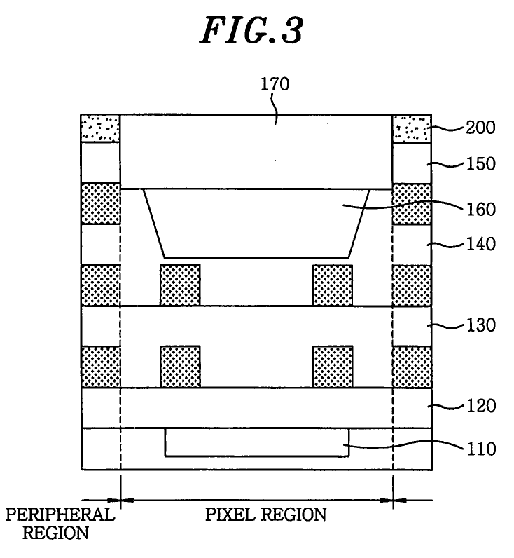

As shown in FIG. 3, a photoresist can be coated on the color filter array 160 to form a photoresist layer 170 having a flat surface. The photoresist layer 170 can be formed on the color filter array 160 by a coating method. Accordingly, the photoresist layer 170 can have a flat surface without the step depending on the location thereof.

The photoresist layer 170, flatted as described above, is hardened. As an example, the photoresist layer 170 may be hardened by thermal treatment.

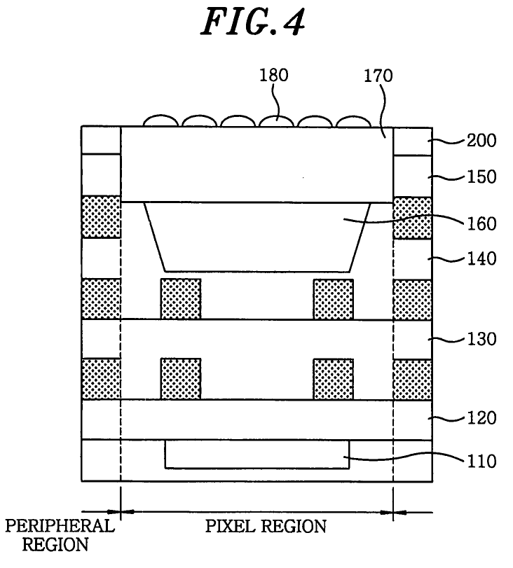

Subsequently, as shown in FIG. 4, a photoresist for forming a dummy micro lens array can be coated on the photoresist layer 170 and then undergo exposure to form a dummy micro lens array 180.

In forming the dummy micro lens array 180, after a pattern is formed through an exposure process, a reflow process may be further performed on the resulting structure.

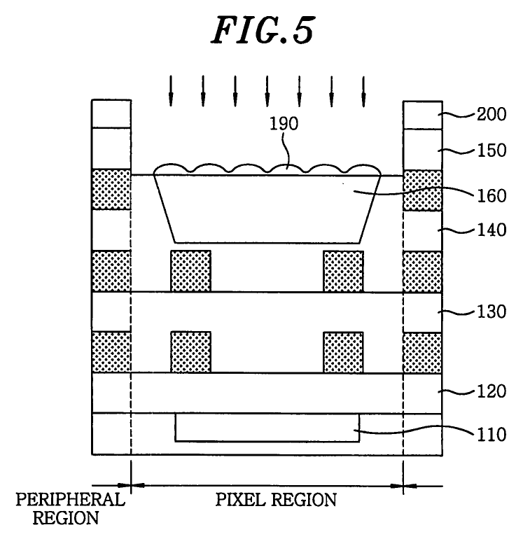

As shown in FIG. 5, an etch process is performed on the dummy micro lens array 180 and the photoresist layer 170. A micro lens array 190 is formed on the color filter array 160.

The etch process on the dummy micro lens array 180 and the photoresist layer 170 may be performed by using an isotropic dry etch method.

By means of the isotropic dry etch, etch process may be performed on the photoresist layer 170 which is disposed below thereof pursuant to the shape of the dummy micro lens array 180.

Accordingly, the micro lens array 190 is formed through this etch process. The micro lens array 190 is formed by the etching of the hardened photoresist layer 170, so that the degree of hardness can be secured.

There are many methods of hardening the photoresist layer 170 known in the prior art. In the present application, a thermal treatment method can be used.

Alternatively, it is possible to form the micro lens array 190 on the surface of the color filter array 160. Since the micro lens array 190 is formed close to the pixel array (110) region as described above, the focal length can be reduced.

As described above, the image sensor according to the present application includes the semiconductor substrate having the pixel region and the peripheral region defined therein and including the pixel array 110 formed in the pixel region, the color filter array 160 formed over the pixel array 110, and the micro lens array 190 formed on the color filter array 160.

Furthermore, the image sensor in accordance with the present application includes the PMD layer 120 formed on the semiconductor substrate, and the first, second, and third IMD layers 130, 140, and 150 formed over the PMD layer 120. The third IMD layer 150 is formed in such a manner that a region formed over the pixel array 110 is etched to a specific depth.

Further, the image sensor according to the present application includes the micro lens array 190 having an increased hardness. The micro lens array 190 can be formed to have consecutive curves without any gap between neighboring lenses. Therefore, a zero gap between neighboring lenses can be implemented in the micro lens array 190.

In accordance with the present application described above, defocusing caused by the step at the boundary of the pixel region and the peripheral region, which was problematic in the prior art, can be solved. Furthermore, according to the present application, it is not necessary to design a dummy pattern as in the prior art, and the cell size can be further reduced.

As mentioned earlier, according to the image sensor and the fabrication method thereof in accordance with the present application, there are advantages in that uniform micro lenses can be formed and the sensitivity of a device can be improved.

While the invention has been shown and described with respect to the preferred embodiment, it will be understood by those skilled in the art that various changes and modifications may be made without departing from the spirit and scope of the invention as defined in the following claims.

What is claimed is:

1. An image sensor comprising:
a semiconductor substrate having a pixel region and a peripheral region defined therein and having a pixel array formed in the pixel region;
a PMD layer formed on the semiconductor substrate;
at least one IMD layer formed over the PMD layer, wherein a region of the IMD layer formed on the pixel array is etched to a specific depth;
a color filter array formed on the etched IMD layer; and
a micro lens array formed on the color filter array, wherein the micro lens array is formed to have consecutive curves without any gap between neighboring lenses.

2. The image sensor of claim 1, wherein the micro lens array is formed on a surface of the color filter array.

3. A method of fabricating an image sensor, comprising the steps of:
providing a semiconductor substrate in which a pixel region and a peripheral region are defined;
forming a pixel array in the pixel region;
forming a PMD layer on the resulting structure;
forming at least one IMD layer over the PMD layer;
etching the IMD layer formed on the pixel array to a specific depth;
forming a color filter array in the etched IMD layer;
coating a photoresist on the color filter array to form a photoresist layer having a flat surface, and hardening the photoresist layer;
coating a photoresist for forming a dummy micro lens array on the photoresist layer, and performing exposure on the photoresist to form the dummy micro lens array; and
performing etch on the dummy micro lens array and the photoresist layer and forming a micro lens array on the color filter array.

4. The method of claim 3, wherein the micro lens array is formed on a surface of the color filter array.

5. The method of claim 3, wherein the etching on the IMD layer is performed by using a Reactive Ion Etch (RIE) method.

6. The method of claim 3, wherein the etching on the dummy micro lens array and the photoresist layer is performed by using an isotropic dry etch method.

7. The method of claim 3, wherein the hardening of the photoresist layer is performed by thermal treatment.

8. A method of fabricating a micro lens array in an image sensor, wherein the image sensor comprises a color filter array formed on a substrate, comprising the steps of:
coating and hardening a photoresist on the color filter array to form a photoresist layer having a flat surface;
coating a photoresist for an array of dummy micro lenses on the photoresist layer and patterning a dummy micro lens array by performing exposure on the photoresist; and
performing etch on the dummy micro lens array and the photoresist layer and forming a micro lens array on the color filter array.

9. The method of claim 8, further comprising the step of reflowing the dummy micro lenses after patterning the dummy micro lens array to thereby allow the dummy micro lenses to have consecutive curves without any gap between neighboring lenses.

10. The method of claim 8, wherein the etching on the dummy micro lens array and the photoresist layer is performed by using an isotropic dry etch method.

11. The method of claim 8, wherein the hardening of the photoresist layer is performed by thermal treatment.
